(19) United States
(12) Patent Application Publication
(10) Pub. No.: US 2016/0122696 A1
(43) Pub. Date: May 5, 2016

(54) COMPOSITIONS AND METHODS FOR REMOVING CERIA PARTICLES FROM A SURFACE

(71) Applicant: ADVANCED TECHNOLOGY MATERIALS, INC., Danbury, CT (US)

(72) Inventors: Jun LIU, Brookfield, CT (US); Laisheng SUN, Danbury, CT (US)

(21) Appl. No.: 14/891,542

(22) PCT Filed: May 14, 2014
(86) PCT No.: PCT/US2014/038125

§ 371 Date: Nov. 16, 2015

Related U.S. Application Data
(60) Provisional application No. 61/824,714, filed on May 17, 2013.

(51) Int. Cl. C11D 11/00; H01L 21/02; C11D 3/33; C11D 3/20; C11D 1/00; C11D 3/30

(52) U.S. Cl. CPC C11D 11/0047; C11D 1/008; C11D 3/30; C11D 3/33; C11D 3/2096; C11D 3/2086; C11D 3/2072; H01L 21/02057

(57) ABSTRACT

A removal composition and process for cleaning post-chemical mechanical polishing (CMP) contaminants and ceria particles from a microelectronic device having said particles and contaminants thereon. The removal compositions include at least one surfactant. The composition achieves highly efficacious removal of the ceria particles and CMP contaminant material from the surface of the microelectronic device without compromising the low-k dielectric, silicon nitride, or tungsten-containing materials.

### FIELD

The present invention relates generally to compositions for removing ceria particles and other chemical mechanical polishing slurry contaminants from microelectronic devices having same thereon.

### DESCRIPTION OF THE RELATED ART

Microelectronic device wafers are used to form integrated circuits. The microelectronic device wafer includes a substrate, such as silicon, into which regions are patterned for deposition of different materials having insulative, conductive or semi-conductive properties.

In order to obtain the correct patterning, excess material used in forming the layers on the substrate must be removed. Further, to fabricate functional and reliable circuitry, it is important to prepare a flat or planar microelectronic wafer surface prior to subsequent processing. Thus, it is necessary to remove and/or polish certain surfaces of a microelectronic device wafer.

Chemical Mechanical Polishing or Planarization (“CMP”) is a process in which material is removed from a surface of a microelectronic device wafer, and the surface is polished (more specifically, planarized) by coupling a physical process such as abrasion with a chemical process such as oxidation or chelation. In its most rudimentary form, CMP involves applying slurry, e.g., a solution of an abrasive and an active chemistry, to a polishing pad that buffs the surface of a microelectronic device wafer to achieve the removal, planarization, and polishing processes. It is not desirable for the removal or polishing process to be comprised of purely physical or purely chemical action, but rather the synergistic combination of both in order to achieve fast, uniform removal. In the fabrication of integrated circuits, the CMP slurry should also be able to preferentially remove films that comprise complex layers of metals and other materials so that highly planar surfaces can be produced for subsequent photolithography, or patterning, etching and thin-film processing.

The front-end-of-the-line (FEOL) method for forming the isolation region in the silicon substrate using the shallow trench isolation (STI) process will now be described.

First, a pad oxide film and a pad nitride film are deposited on a semiconductor substrate, and patterned to expose portions of the substrate, which correspond to an isolation region. Then, the exposed region of the substrate is etched to form a trench. Thereafter, the substrate is subjected to a sacrificial oxidation process to remove damage caused by the substrate etching, and then, a wall oxide film is formed on the surface of the trench. Next, a trench-buried oxide film, for example, an oxide film formed by high density plasma chemical vapor deposition (hereinafter, referred to as HDP-oxide film), is deposited on the surface of the substrate in such a manner as to be buried in the trench. Then, the surface of the HDP-oxide film is subjected to chemical mechanical polishing (hereinafter, referred to as CMP) until the pad nitride film is exposed. Then, the resulting substrate is cleaned, after which the pad nitride film which was used as an etch barrier during the trench etch is removed, thereby completing the formation of an isolation region.

A CMP slurry using ceria particles has a feature whereby it achieves a faster polishing speed for an insulator, relative to a silica-containing slurry. Moreover, a ceria-based slurry is most often used because of the ability to achieve STI pattern planarization with minimal oxide erosion. Disadvantageously, ceria-based slurries are difficult to remove from STI structures because of the oppositely charged zeta potentials of the ceria particles relative to the silicon oxide and silicon nitride surfaces. If a device is manufactured with these residues remaining on the wafer, the residues will lead to short circuits and an increase in electric resistance. Ceria particles are also a problem with FinFET structures following CMP processing using ceria slurries.

Currently the most efficient wet cleaning formulation is dilute hydrofluoric acid (DHF), however, DHF disadvantageously etches silicon oxide and other low-k dielectric materials.

A need remains in the art for a ceria particle removal composition and process that effectively removes ceria particles from a surface of a microelectronic device while not damaging the underlying materials such as silicon nitride, low-k dielectrics (e.g., silicon oxide), and tungsten-containing layers. The ceria particle removal composition should also efficaciously remove CMP slurry contaminants from the surface of the microelectronic device.

### SUMMARY

The present invention generally relates to a composition and process for cleaning ceria particles and CMP contaminants from microelectronic devices having said particles and CMP contaminants thereon.

In one aspect, an aqueous removal composition is described, said composition comprising at least one quaternary base, at least one complexing agent, at least one reducing agent, and at least one surfactant.

In another aspect, a method of removing ceria particles and CMP contaminants from a microelectronic device having said particles and contaminants thereon is described, said method comprising contacting the microelectronic device with a removal composition for sufficient time to at least partially clean said particles and contaminants from the microelectronic device, wherein said removal composition comprises at least one quaternary base, at least one complexing agent, at least one reducing agent, and at least one surfactant.

In still another aspect, an article of manufacture is described, said article comprising an aqueous removal composition, a microelectronic device wafer, and material selected from the group consisting of ceria particles, CMP contaminants and combinations thereof, wherein the cleaning composition comprises at least one quaternary base, at least one complexing agent, at least one reducing agent, and at least one surfactant.

Other aspects, features and advantages will be more fully apparent from the ensuing disclosure and appended claims.

### DETAILED DESCRIPTION, AND PREFERRED EMBODIMENTS THEREOF

The present invention relates generally to compositions useful for the removal of ceria particles and CMP contaminants from a microelectronic device having such material(s) thereon. Advantageously, the ceria particles and CMP contaminants are efficaciously removed while still being compatible with silicon nitride and low-k dielectric (e.g., silicon oxide) layers. In addition, the compositions described herein are compatible with conductive metals such as tungsten.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

As used herein, “ceria particles” corresponds to the abrasive particles used in chemical mechanical polishing slurries, for example, a cerium oxide having the formula Ce₂O₃ and CeO₂. It should be appreciated that the “ceria particles” may comprise, consist of, or consist essentially of cerium oxide.

As used herein, “contaminants” correspond to chemicals present in the CMP slurry, reaction by-products of the polishing slurry, post-CMP residue, chemicals present in the wet etching composition, reaction by products of the wet etching composition, and any other materials that are the by-products of the CMP process, the wet etching, the plasma etching or the plasma ashing process.

As used herein, “post-CMP residue” corresponds to particles from the polishing slurry, e.g., chemicals present in the slurry, reaction by-products of the polishing slurry, carbon-rich particles, polishing pad particles, brush deloading particles, equipment materials of construction particles, metal, organic residues, and any other materials that are the by-products of the CMP process. In addition, if tungsten was removed during the CMP process, the post-CMP residue can further comprise tungsten-containing particles.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, “complexing agent” includes those compounds that are understood by one skilled in the art to be complexing agents, chelating agents and/or sequestering agents. Complexing agents will chemically combine with or physically hold the metal atom and/or metal ion to be removed using the compositions described herein.

“Substantially devoid” is defined herein as less than 2 wt. %, preferably less than 1 wt. %, more preferably less than 0.5 wt. %, and most preferably less than 0.1 wt. %. “Devoid” is intended to correspond to less than 0.001 wt % to account for environmental contamination.

As used herein, “about” is intended to correspond to ±5% of the stated value.

As used herein, “oxidizing agents” correspond to compounds that oxidize exposed metal(s) resulting in corrosion of the metal or oxide formation on the metal. Oxidizing agents include, but are not limited to: hydrogen peroxide; other percompounds such as salts and acids containing peroxomonosulfate, perborate, perchlorate, periodate, persulfate, permanganate, and peracetate anions; and amine-N-oxides.

As used herein, “fluoride containing compounds” correspond to salt or acid compound comprising a fluoride ion (F⁻) that is ionically bonded to another atom.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, tungsten, and other refractory metals and their nitrides and silicides.

For the purposes of this disclosure, “degradation products of adenosine and adenosine derivatives” includes, but is not limited to, adenine (C₅H₅N₅), methylated adenine (e.g., N-methyl-7H-purin-6-amine, C₆H₇N₅), dimethylated adenine (e.g., N,N-dimethyl-7H-purin-6-amine, C₇H₉N₅), N4,N4-dimethylpyrimidine-4,5,6-triamine (C₆H₁₁N₅), 4,5,6-triaminopyrimidine, allantoin (C₄H₆N₄O₃), hydroxylated C—O—O—C dimers ((C₅H₄N₅O₂)₂), C—C bridged dimers ((C₅H₄N₅)₂ or (C₅H₄N₅O)₂), ribose (C₅H₁₀O₅), methylated ribose (e.g., 5-(methoxymethyl)tetrahydrofuran-2,3,4-triol, C₆H₁₂O₅), tetramethylated ribose (e.g., 2,3,4-trimethoxy-5-(methoxymethyl)tetrahydrofuran, C₉H₁₈O₅), and other ribose derivatives such as methylated hydrolyzed diribose compounds.

As used herein, “suitability” for removing ceria particles and CMP contaminants from a microelectronic device having said particles and contaminants thereon corresponds to at least partial removal of said particles/contaminants from the microelectronic device. Cleaning efficacy is rated by the reduction of objects on the microelectronic device. For example, pre- and post-cleaning analysis may be carried out using an atomic force microscope. The particles on the sample may be registered as a range of pixels. A histogram (e.g., a Sigma Scan Pro) may be applied to filter the pixels in a certain intensity, e.g., 231-235, and the number of particles counted. The particle reduction may be calculated using:

$$Cleaning Efficacy = \frac{( \begin{matrix}Number of PreClean Objects - \\ Number of PostClean Objects\end{matrix} )}{Number of PreClean Objects} \times 100$$

Notably, the method of determination of cleaning efficacy is provided for example only and is not intended to be limited to same. Alternatively, the cleaning efficacy may be considered as a percentage of the total surface that is covered by particulate matter. For example, AFM's may be programmed to perform a z-plane scan to identify topographic areas of interest above a certain height threshold and then calculate the area of the total surface covered by said areas of interest. One skilled in the art would readily understand that the less area covered by said areas of interest post-cleaning, the more efficacious the removal composition. Preferably, at least 75% of the particles/contaminants are removed from the microelectronic device using the compositions described herein, more preferably at least 90%, even more preferably at least 95%, and most preferably at least 99% of the particles/contaminants are removed.

Compositions described herein may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

In a first aspect, a removal composition is described, said aqueous removal composition comprising, consisting of, or consisting essentially of at least one quaternary base and at least one surfactant. In another embodiment, the aqueous removal composition comprises, consists of, or consists essentially of at least one complexing agent and at least one surfactant. In still another embodiment, the aqueous removal composition comprises, consists of, or consists essentially of at least one reducing agent and at least one surfactant. In another embodiment, the aqueous removal composition comprises, consists of, or consists essentially of at least one quaternary base, at least one complexing agent, and at least one surfactant. In still another embodiment, the aqueous removal composition comprises, consists of, or consists essentially of at least one reducing agent, at least one complexing agent, and at least one surfactant. In yet another embodiment, the aqueous removal composition comprises, consists of, or consists essentially of at least one quaternary base, at least one reducing agent, and at least one surfactant. In another embodiment, the aqueous removal composition comprises, consists of, or consists essentially of at least one quaternary base, at least one complexing agent, at least one reducing agent, and at least one surfactant. Each embodiment can further include at least one corrosion inhibitor.

In each embodiment, the removal composition is substantially devoid of at least one of oxidizing agents; fluoride-containing sources; chemical mechanical polishing abrasive materials (e.g., silica, alumina, etc.); alkali and/or alkaline earth metal bases; and corrosion inhibitors selected from the group consisting of cyanuric acid, barbituric acid and derivatives thereof, glucuronic acid, squaric acid, alpha-keto acids, adenosine and derivatives thereof, ribosylpurines and derivatives thereof, purine compounds and derivatives thereof, degradation products of adenosine and adenosine derivatives, triaminopyrimidine and other substituted pyrimidines, purine-saccharide complexes, phosphonic acid and derivatives thereof, phenanthroline, glycine, nicotinamide and derivatives thereof, flavonoids such as flavonols and anthocyanins and derivatives thereof, and combinations thereof, prior to removal of residue material from the microelectronic device. In addition, the removal compositions should not solidify to form a polymeric solid, for example, photoresist.

It is understood by the skilled artisan that the aqueous cleaning composition described herein comprises water, preferably deionized water.

Complexing agents contemplated include species having the general formula NR¹R²R³, wherein R¹, R² and R³ may be the same as or different from one another and are selected from the group consisting of hydrogen, straight-chained or branched C₁-C₆ alkyl (e.g., methyl, ethyl, propyl, butyl, pentyl, and hexyl), straight-chained or branched C₁-C₆ alcohol (e.g., methanol, ethanol, propanol, butanol, pentanol, and hexanol), and straight chained or branched ethers having the formula R⁴—O—R⁵, where R⁴ and R⁵ may be the same as or different from one another and are selected from the group consisting of C₁-C₆ alkyls as defined above. Most preferably, at least one of R¹, R² and R³ is a straight-chained or branched C₁-C₆ alcohol. Examples include, without limitation, alkanolamines such as aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, other C₁-C₈ alkanolamines and combinations thereof. When the amine includes the ether component, the amine may be considered an alkoxyamine, e.g., 1-methoxy-2-aminoethane. Alternatively, or in addition to the NR¹R²R³ amine, the complexing agent may be a multi-functional amine including, but not limited to, 4-(2-hydroxyethyl)morpholine (HEM), N-aminoethylpiperazine (N-AEP), 1,2-cyclohexanediamine-N,N,N′,N′-tetraacetic acid (CDTA), ethylenediaminetetraacetic acid (EDTA), m-xylenediamine (MXDA), iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, and combinations thereof. Alternatively, or in addition to the NR¹R²R³ amine and/or the multi-functional amine, the complexing agent can include organic acids comprising at least one COOH group or carboxylate group in a salt thereof, including, but not limited to, lactic acid, maleic acid, malic acid, citric acid, benzoic acid, fumaric acid, succinic acid, oxalic acid, malonic acid, mandelic acid, maleic anhydride, phthalic acid, glutaric acid, glycolic acid, glyoxylic acid, itaconic acid, phenylacetic acid, quinic acid, pyromellitic acid, tartaric acid, terephthalic acid, trimellitic acid, trimesic acid, gluconic acid, glyceric acid, formic acid, acetic acid, propionic acid, acrylic acid, adipic acid, itaconic acid, pyrocatechol, pyrogallol, tannic acid, other aliphatic and aromatic carboxylic acids, salts thereof as well as combinations of the foregoing acids Preferably, the at least one complexing agent comprises a species selected from the group consisting of monoethanolamine, triethanolamine, EDTA, and combinations thereof. It is contemplated that the removal composition be substantially amine-free, i.e., the at least one complexing agent comprises at least one organic acid as described herein.

Quaternary bases contemplated herein include compounds having the formula NR¹R²R³R⁴OH, wherein R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl. Tetraalkylammonium hydroxides that are commercially available include tetraethylammonium hydroxide (TEAH), tetramethylammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), and combinations thereof, may be used. Tetraalkylammonium hydroxides which are not commercially available may be prepared in a manner analogous to the published synthetic methods used to prepare TMAH, TEAH, TPAH, TBAH, TBMAH, and BTMAH, which are known to one ordinary of skill in the art. Another widely used quaternary ammonium base is choline hydroxide. Preferably, the quaternary base comprises TMAH.

The reducing agents include, but are not limited to, ascorbic acid, L(+)-ascorbic acid, isoascorbic acid, ascorbic acid derivatives, gallic acid, glyoxal, and combinations thereof. In a particularly preferred embodiment, the cleaning composition includes ascorbic acid. In another particularly preferred embodiment, the cleaning composition includes ascorbic acid and gallic acid.

The surfactants include non-ionic surfactants and anionic polymers, which include polymers prepared by anionic polymerization reactions. Anionic polymers include, but are not limited to, polyacrylic acid; polyacrylic acid esters and analogoues of polyacrylic acid esters; polyaminoacids such as polyalanine, polyleucine, polyglycine, etc.; polyamidohydroxyurethanes; polylactones; polyacrylamides; poly(acrylamide-co-diallyldiemethylammonium chloride); poly(acrylamide); poly(diallyldiemethylammonium chloride); diallyldimethylammonium chloride; acetoguanamine; polyglutamic acid; hyaluronic acid; alginic acid; carboxymethylcellulose; copolymers of vinyl acetate and crotonic acid; dextran sulfate; heparan sulfate; and combinations thereof. Non-ionic surfactants contemplated include, but are not limited to, polyoxyethylene lauryl ether (Emalmin NL-100 (Sanyo), Brij 30, Brij 98, Brij 35), dodecenylsuccinic acid monodiethanol amide (DSDA, Sanyo), ethylenediamine tetrakis (ethoxylate-block-propoxylate) tetrol (Tetronic 90R4), polyethylene glycols (e.g., PEG400), polypropylene glycols, polyethylene or polypropylene glycol ethers, block copolymers based on ethylene oxide and propylene oxide (Newpole PE-68 (Sanyo), Pluronic L31, Pluronic 31R1, Pluronic L61, Pluronic F-127), polyoxypropylene sucrose ether (SN008S, Sanyo), t-octylphenoxypolyethoxyethanol (Triton X100), 10-ethoxy-9,9-dimethyldecan-1-amine (TRITON® CF-32), Polyoxyethylene (9) nonylphenylether, branched, Polyoxyethylene (40) nonylphenylether, branched (e.g., IGEPAL Co 890), dinonylphenyl polyoxyethylene, nonylphenol alkoxylates (e.g., SURFONIC LF-41), polyoxyethylene sorbitol hexaoleate, polyoxyethylene sorbitol tetraoleate, polyethylene glycol sorbitan monooleate (Tween 80), sorbitan monooleate (Span 80), a combination of Tween 80 and Span 80, alcohol alkoxylates (e.g., Plurafac RA-20), alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives such as SIS6952.0 (Siliclad, Gelest), siloxane modified polysilazane such as PP1-SG10 Siliclad Glide 10 (Gelest), silicone-polyether copolymers such as Silwet L-77 (Setre Chemical Company), Silwet ECO Spreader (Momentive), and ethoxylated fluorosurfactants (ZONYL® FSO, ZONYL® FSN-100). Preferably, the at least one surfactant comprises polyacrylic acid, polyacrylic acid esters, analogoues of polyacrylic acid esters, and combinations thereof.

The aqueous removal compositions can further comprise at least one corrosion inhibitor, where the corrosion inhibitor component is added to the aqueous cleaning composition to lower the corrosion rate of metals, e.g., copper, aluminum, tungsten, barrier materials, as well as enhance the cleaning performance. Corrosion inhibitors contemplated include, but are not limited to benzotriazole, citric acid, ethylenediamine, tannic acid, 1,2,4-triazole (TAZ), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1,2,3-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, benzoic acid, ammonium benzoate, catechol, pyrogallol, resorcinol, hydroquinone, propanethiol, benzohydroxamic acids, heterocyclic nitrogen inhibitors, potassium ethylxanthate, and combinations thereof. When present, the amount of corrosion inhibitor is in a range from about 0.001 wt % to about 2 wt %, based on the total weight of the composition.

The aqueous removal composition is particularly useful for removing ceria particles and contaminants, e.g., post-CMP residue and contaminants from a microelectronic device structure. The pH of the aqueous removal compositions described herein is greater than 7, preferably in a range from about 7 to about 14, more preferably in a range from about 10 to about 14.

In a particularly preferred embodiment, the aqueous removal composition comprises, consists of, or consists essentially of tetramethylammonium hydroxide, at least one complexing agent, at least one reducing agent, polyacrylic acid, and water. For example, the aqueous removal composition can comprise, consist of or consist essentially of tetramethylammonium hydroxide, monoethanolamine, ascorbic acid, polyacrylic acid, and water. Alternatively, the removal composition can comprise, consist of, or consist essentially of tetramethylammonium hydroxide, monoethanolamine, EDTA, ascorbic acid, polyacrylic acid, and water.

With regards to compositional amounts, the weight percent ratios of each component is preferably as follows: about 0.1:1 to about 50:1 complexing agent(s) to quaternary base(s), preferably about 0.5:1 to about 10:1, and most preferably about 0.5:1 to about 5:1; about 0.1:1 to about 30:1 reducing agent(s) to quaternary base(s), preferably about 0.5:1 to about 10:1, and most preferably about 0.5:1 to about 5:1; and about 0.01:1 to about 20:1 polymeric species(s) to quaternary base(s), preferably about 0.1:1 to about 10:1, and most preferably about 0.1:1 to about 1:1. Most preferably, the pH of the removal composition is greater than 12.

The range of weight percent ratios of the components will cover all possible concentrated or diluted embodiments of the composition. Towards that end, in one embodiment, a concentrated removal composition is provided that can be diluted for use as a cleaning solution. A concentrated composition, or “concentrate,” advantageously permits a user, e.g. CMP process engineer, to dilute the concentrate to the desired strength and pH at the point of use. Dilution of the concentrated aqueous removal composition may be in a range from about 1:1 to about 2500:1, preferably about 5:1 to about 200:1, and most preferably about 10:1 to about 60:1, wherein the aqueous removal composition is diluted at or just before the tool with solvent, e.g., deionized water. It is to be appreciated by one skilled in the art that following dilution, the range of weight percent ratios of the components disclosed herein should remain unchanged.

The compositions described herein may have utility in applications including, but not limited to, post-etch residue removal, post-ash residue removal surface preparation, post-plating cleaning and post-CMP residue removal. In addition, it is contemplated that the aqueous cleaning compositions described herein may be useful for the cleaning and protection of other metal (e.g., copper-containing and tungsten-containing) products including, but not limited to, decorative metals, metal wire bonding, printed circuit boards and other electronic packaging using metal or metal alloys.

In yet another preferred embodiment, the aqueous removal compositions described herein further include ceria particles and/or CMP contaminants The ceria particles and contaminants become a component of the removal composition after cleaning has begun and will be dissolved and/or suspended in the compositions.

The aqueous removal compositions are easily formulated by simple addition of the respective ingredients and mixing to homogeneous condition. Furthermore, the compositions may be readily formulated as single-package formulations or multi-part formulations that are mixed at or before the point of use, e.g., the individual parts of the multi-part formulation may be mixed at the tool or in a storage tank upstream of the tool. The concentrations of the respective ingredients may be widely varied in specific multiples of the composition, i.e., more dilute or more concentrated, and it will be appreciated that the compositions described herein can variously and alternatively comprise, consist or consist essentially of any combination of ingredients consistent with the disclosure herein.

Accordingly, another aspect relates to a kit including, in one or more containers, one or more components adapted to form the compositions described herein. The kit may include, in one or more containers, at least one quaternary base, at least one complexing agent, at least one reducing agent, and at least one surfactant, for combining with additional solvent, e.g., water, at the fab or the point of use. The containers of the kit must be suitable for storing and shipping said cleaning compositions, for example, NOWPak® containers (Advanced Technology Materials, Inc., Danbury, Conn., USA).

The one or more containers which contain the components of the aqueous removal composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and PCT/US08/63276 entitled “SYSTEMS AND METHODS FOR MATERIAL BLENDING AND DISTRIBUTION” filed on May 9, 2008 in the name of Advanced Technology Materials, Inc.

As applied to microelectronic manufacturing operations, the aqueous removal compositions described herein are usefully employed to clean ceria particles and/or CMP contaminants (e.g., post-CMP residue and contaminants) from the surface of the microelectronic device. The aqueous removal compositions do not damage low-k dielectric materials (e.g., silicon oxide), silicon nitride layers, or tungsten-containing layers on the device surface. Preferably the aqueous removal compositions remove at least 85% of the ceria particles present on the device prior to particles removal, more preferably at least 90%, even more preferably at least 95%, and most preferably at least 99%.

In post-CMP particle and contaminant removal application, the aqueous removal composition may be used with a large variety of conventional cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-Mesa™/Reflexion™/Reflexion LK™, and Megasonic batch wet bench systems.

In use of the compositions described herein for removing ceria particles and CMP contaminants from microelectronic devices having same thereon, the aqueous removal composition typically is contacted with the device for a time of from about 5 sec to about 10 minutes, preferably about 1 sec to 20 min, preferably about 15 sec to about 5 min at temperature in a range of from about 20° C. to about 90° C., preferably about 20° C. to about 50° C. Such contacting times and temperatures are illustrative, and any other suitable time and temperature conditions may be employed that are efficacious to at least partially remove the ceria particles and CMP contaminants from the device, within the broad practice of the method. “At least partially clean” and “substantial removal” both correspond to at removal of at least 85% of the ceria particles present on the device prior to particle removal, more preferably at least 90%, even more preferably at least 95%, and most preferred at least 99%

Following the achievement of the desired particle removal action, the aqueous removal composition may be readily removed from the device to which it has previously been applied, as may be desired and efficacious in a given end use application of the compositions described herein. Preferably, the rinse solution includes deionized water. Thereafter, the device may be dried using nitrogen or a spin-thy cycle.

Yet another aspect relates to the improved microelectronic devices made according to the methods described herein and to products containing such microelectronic devices.

Another aspect relates to a recycled aqueous removal composition, wherein the removal composition may be recycled until particle and/or contaminant loading reaches the maximum amount the aqueous removal composition may accommodate, as readily determined by one skilled in the art.

A still further aspect relates to methods of manufacturing an article comprising a microelectronic device, said method comprising contacting the microelectronic device with an aqueous removal composition for sufficient time to remove ceria particles and CMP contaminants from the microelectronic device having said particles and contaminants thereon, and incorporating said microelectronic device into said article, using a removal composition described herein.

In another aspect, a method of removing ceria particles and CMP contaminants from a microelectronic device having same thereon is described, said method comprising:
polishing the microelectronic device with a CMP slurry, wherein the CMP slurry comprises ceria particles;
contacting the microelectronic device with an aqueous removal composition comprising at least one quaternary base, at least one complexing agent, at least one reducing agent, and at least one surfactant, for a sufficient time to remove ceria particles and CMP contaminants from the microelectronic device to form a post-CMP particle-containing composition; and
continuously contacting the microelectronic device with the post-CMP particle-containing composition for a sufficient amount of time to effect substantial cleaning of the microelectronic device.

Another aspect relates to an article of manufacture comprising an aqueous removal composition, a microelectronic device wafer, and material selected from the group consisting of ceria particles, CMP contaminants and combinations thereof, wherein the removal composition comprises at least one quaternary base, at least one complexing agent, at least one reducing agent, and at least one surfactant.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

1. An aqueous removal composition comprising at least one quaternary base, at least one complexing agent, at least one reducing agent, and at least one surfactant.

2. The aqueous removal composition of claim 1, wherein the at least one surfactant comprises a species selected from the group consisting of polyacrylic acid, polyacrylic acid esters and analogoues of polyacrylic acid esters, polyalanine, polyleucine, polyglycine, polyamidohydroxyurethanes, polylactones, polyacrylamides, poly(acrylamide-co-diallyldiemethylammonium chloride), poly(acrylamide), poly(diallyldiemethylammonium chloride), diallyldimethylammonium chloride, acetoguanamine, polyglutamic acid, hyaluronic acid, alginic acid, carboxymethylcellulose, copolymers of vinyl acetate and crotonic acid, dextran sulfate, heparan sulfate, polyoxyethylene lauryl ether, dodecenylsuccinic acid monodiethanol amide, ethylenediamine tetrakis (ethoxylate-block-propoxylate) tetrol, polyethylene glycols, polypropylene glycols, polyethylene glycol ethers, polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether (branched), Polyoxyethylene (40) nonylphenylether (branched), dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, a combination of Tween 80 and Span 80, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazane, silicone-polyether copolymers, ethoxylated fluorosurfactants, and combinations thereof.

3. The aqueous removal composition of claim 1, wherein the at least one surfactant comprises polyacrylic acid, polyacrylic acid esters, analogoues of polyacrylic acid esters, and combinations thereof.

4. The aqueous removal composition of claim 1, wherein the at least one complexing agent comprises a species selected from the group consisting of aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, 1-methoxy-2-aminoethane, 4-(2-hydroxyethyl)morpholine (HEM), N-aminoethylpiperazine (N-AEP), 1,2-cyclohexanediamine-N,N,N′,N′-tetraacetic acid (CDTA), ethylenediaminetetraacetic acid (EDTA), m-xylenediamine (MXDA), iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, glycine, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, lactic acid, maleic acid, malic acid, citric acid, benzoic acid, fumaric acid, succinic acid, oxalic acid, malonic acid, mandelic acid, maleic anhydride, phthalic acid, glutaric acid, glycolic acid, glyoxylic acid, itaconic acid, phenylacetic acid, quinic acid, pyromellitic acid, tartaric acid, terephthalic acid, trimellitic acid, trimesic acid, gluconic acid, glyceric acid, formic acid, acetic acid, propionic acid, acrylic acid, adipic acid, itaconic acid, pyrocatechol, pyrogallol, tannic acid, and combinations thereof.

5. The aqueous removal composition of claim 1, wherein the at least one complexing agent comprises monoethanolamine, EDTA, or a combination of monoethanolamine and EDTA.

6. The aqueous removal composition of claim 1, wherein the at least one quaternary base comprises a species selected from the group consisting of tetraethylammonium hydroxide (TEAH), tetramethylammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, and combinations thereof.

7. The aqueous removal composition of claim 1, wherein the at least one quaternary base comprises tetramethylammonium hydroxide.

8. The aqueous removal composition of claim 1, wherein the at least one reducing agent comprises a species selected from the group consisting of ascorbic acid, L(+)-ascorbic acid, isoascorbic acid, ascorbic acid derivatives, gallic acid, glyoxal, and combinations thereof.

9. The aqueous removal composition of claim 1, wherein the at least one reducing agent comprises ascorbic acid.

10. (canceled)

11. (canceled)

12. The aqueous removal composition of claim 1, wherein the composition further comprises at least one corrosion inhibitor.

13. The aqueous removal composition of claim 1, wherein the pH of the composition is in a range from about 7 to about 14.

14. The aqueous removal composition of claim 1, wherein the aqueous cleaning composition is substantially devoid of at least one of: oxidizing agents; fluoride-containing sources; chemical mechanical polishing abrasive materials; alkali bases, alkaline earth metal bases; and corrosion inhibitors selected from the group consisting of cyanuric acid, barbituric acid and derivatives thereof, glucuronic acid, squaric acid, alpha-keto acids, adenosine and derivatives thereof, ribosylpurines and derivatives thereof, purine compounds and derivatives thereof, degradation products of adenosine and adenosine derivatives, triaminopyrimidine and other substituted pyrimidines, purine-saccharide complexes, phosphonic acid and derivatives thereof, phenanthroline, glycine, nicotinamide and derivatives thereof, flavonoids such as flavonols and anthocyanins and derivatives thereof, and combinations thereof, prior to removal of residue material from the microelectronic device.

15. The aqueous removal composition of claim 1, wherein the composition is useful for removing ceria particles and CMP contaminants from a microelectronic device structure.

16. A method of removing ceria particles and CMP contaminants from a microelectronic device having said particles and contaminants thereon, said method comprising contacting the microelectronic device with a removal composition for sufficient time to at least partially clean said particles and contaminants from the microelectronic device, wherein the removal composition comprises at least one quaternary base, at least one complexing agent, at least one reducing went, and at least one surfactant.

17. The method of claim 16, wherein the CMP contaminants comprises material selected from the group consisting of CMP slurry, reaction by-products of the polishing slurry, post-CMP residue, chemicals present in the wet etching composition, reaction by products of the wet etching composition, and any other materials that are the by-products of the CMP process, the wet etching, the plasma etching or the plasma ashing process.

18. The method of claim 16, further comprising diluting the removal composition with solvent at or before a point of use, wherein said solvent comprises water.

19. An article of manufacture comprising an aqueous removal composition, a microelectronic device wafer, and material selected from the group consisting of ceria particles, CMP contaminants and combinations thereof, wherein the cleaning composition comprises at least one quaternary base, at least one complexing agent, at least one reducing agent, and at least one surfactant.

20. The method of claim 16, wherein the at least one surfactant comprises a species selected from the group consisting of polyacrylic acid, polyacrylic acid esters and analogoues of polyacrylic acid esters, polyalanine, polyleucine, polyglycine, polyamidohydroxyurethanes, polylactones, polyacrylamides, poly(acrylamide-co-diallyldiemethylammonium chloride), poly(acrylamide), poly(diallyldiemethylammonium chloride), diallyldimethylammonium chloride, acetoguanamine, polyglutamic acid, hyaluronic acid, alginic acid, carboxymethylcellulose, copolymers of vinyl acetate and crotonic acid, dextran sulfate, heparan sulfate, polyoxyethylene lauryl ether, dodecenylsuccinic acid monodiethanol amide, ethylenediamine tetrakis (ethoxylate-block-propoxylate) tetrol, polyethylene glycols, polypropylene glycols, polyethylene glycol ethers, polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether (branched), Polyoxyethylene (40) nonylphenylether (branched), dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, a combination of Tween 80 and Span 80, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazane, silicone-polyether copolymers, ethoxylated fluorosurfactants, and combinations thereof;
wherein the at least one complexing agent comprises a species selected from the group consisting of aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, 1-methoxy-2-aminoethane, 4-(2-hydroxyethyl)morpholine (HEM), N-aminoethylpiperazine (N-AEP), 1,2-cyclohexanediamine-N,N,N′,N′-tetraacetic acid (CDTA), ethylenediaminetetraacetic acid (EDTA), m-xylenediamine (MXDA), iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, glycine, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, lactic acid, maleic acid, malic acid, citric acid, benzoic acid, fumaric acid, succinic acid, oxalic acid, malonic acid, mandelic acid, maleic anhydride, phthalic acid, glutaric acid, glycolic acid, glyoxylic acid, itaconic acid, phenylacetic acid, quinic acid, pyromellitic acid, tartaric acid, terephthalic acid, trimellitic acid, trimesic acid, gluconic acid, glyceric acid, formic acid, acetic acid, propionic acid, acrylic acid, adipic acid, itaconic acid, pyrocatechol, pyrogallol, tannic acid, and combinations thereof;
wherein the at least one quaternary base comprises a species selected from the group consisting of tetraethylammonium hydroxide (TEAH), tetramethylammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, and combinations thereof; and
wherein the at least one reducing agent comprises a species selected from the group consisting of ascorbic acid, L(+)-ascorbic acid, isoascorbic acid, ascorbic acid derivatives, gallic acid, glyoxal, and combinations thereof.

21. The aqueous removal composition of claim 1, wherein the weight percent ratios of complexing agent(s) to quaternary base(s) is about 0.1:1 to about 50:1, reducing agent(s) to quaternary base(s) is about 0.1:1 to about 30:1; and polymeric species(s) to quaternary base(s) is about 0.01:1 to about 20:1.
